(19) United States
(12) Patent Application Publication
(10) Pub. No.: US 2009/0121354 A1
(43) Pub. Date: May 14, 2009

(54) Semiconductor Device and Method of Fabricating the Same

(75) Inventor: Min Chul Gil, Icheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/147,150

(22) Filed: Jun. 26, 2008

(30) Foreign Application Priority Data
Nov. 9, 2007 (KR) 2007-114437

(51) Int. Cl. H01L 23/52; H01L 21/4763

(52) U.S. Cl. 257/751; 438/643; 257/E21.495; 257/E23.141

(57) ABSTRACT

In a method of fabricating a semiconductor device a plurality of metal lines is formed over a semiconductor substrate. A reaction-prevention layer is formed on the metal line of a region in which a via hole will be formed. An interlayer insulating layer is formed over the semiconductor substrate including the reaction-prevention layer. The via hole is formed by etching the interlayer insulating layer over the reaction-prevention layer. A via plug is formed within the via hole.

### CROSS-REFERENCES TO RELATED APPLICATIONS

The present application claims priority to Korean patent application number 10-2007-0114437, filed on Nov. 9, 2007, which is incorporated by reference in its entirety.

### BACKGROUND OF THE INVENTION

The present invention relates to semiconductor devices and methods of fabricating the same and, more particularly, to semiconductor devices and methods of fabricating the same that can solve a problem that degrades reliability of the devices occurring in a process of forming a via plug electrically connecting metal lines.

A semiconductor device includes a plurality of memory cells, select transistors and high voltage transistors. A NAND flash memory device is a memory device that reads information sequentially. Program and erase operations of this NAND flash memory device are performed by controlling the threshold voltage (Vt) of a memory cell while injecting or discharging electrons into or from a floating gate by F-N tunneling.

In NAND flash memory devices, a contact plug is necessary to electrically connect an external driving voltage, applied through metal lines, to underlying semiconductor structure layers (for example, a source region and a drain region, that is, junctions). In NAND flash memory devices, the contact plugs largely include a source contact plug (SRCT), a drain contact plug (DRCT), and a metal contact plug. The source contact plug functions to connect a source region of a cell, formed in an active region, and an upper metal line (for example, a common source line). The drain contact plug functions to electrically connect a drain region of the cell and an upper metal line (for example, a bit line). The metal contact plug functions to electrically connect the source region or the drain region of the cell, formed in the active region, and the metal line. The source contact plug, the drain contact plug, and the metal contact plug are formed simultaneously with the metal line.

A process of forming the contact plug that electrically connects metal lines, of the conventional process of forming a NAND flash memory device, is described in short below. Bit line damascene patterns are formed. In order to form a tungsten (W) plug to electrically connect the metal patterns, via hole etch is performed. A tungsten (W) plug metal barrier layer is formed at the bottom and on the sidewalls of the via hole and tungsten (W) is then deposited.

However, in the case in which the via hole is not partially gap-filled with tungsten (W) plug metal in the process of forming the tungsten (W) plug metal barrier layer and the deposition process of tungsten (W), a tungsten-copper (W-Cu) solid body A can be formed at a portion where capping of the tungsten (W) plug metal barrier layer is poor due to the incorporation of copper (Cu) elements, as shown in FIG. 1A. Accordingly, as shown in FIG. 1B, upon WEB etch, a un-etch residue B remains due to the tungsten (W)-copper (Cu) solid body A. Thus, problems, such as pattern issues and a bridge C with neighboring via holes, are generated in subsequent processes, as shown in FIG. 1C. Consequently, a problem arises because reliability of devices is degraded.

### BRIEF SUMMARY OF THE INVENTION

The present invention is directed towards semiconductor devices and methods of fabricating the same that can solve a problem that degrades reliability of the devices occurring in a process of forming a via plug electrically connecting metal lines.

In a method of manufacturing a semiconductor device according to an embodiment of the present invention, a plurality of metal lines may be formed over a semiconductor substrate. A reaction-prevention layer may be formed on the metal line of a region in which a via hole will be formed. An interlayer insulating layer may be formed over the semiconductor substrate including the reaction-prevention layer. The via hole may be formed by etching the interlayer insulating layer over the reaction-prevention layer. A via plug may be formed within the via hole.

After the reaction-prevention layer is formed, a diffusion-prevention layer may be further formed on the interlayer insulating layer including the metal lines.

The diffusion-prevention layer may be formed of a nitride layer.

The metal lines may be formed from copper (Cu).

The reaction-prevention layer may be formed of any one of tantalum nitride (TaN), titanium (Ti) and titanium nitride (TiN) or a stacked layer including two or more of TaN, Ti and TiN.

The via plug can be formed from tungsten (W).

The reaction-prevention layer can have a width wider than that of the via plug.

A semiconductor device according to a preferred embodiment of the present invention may include a plurality of metal lines formed over a semiconductor substrate, a reaction-prevention layer formed on the metal line of a region in which a via hole will be formed, an interlayer insulating layer including a via hole formed on the reaction-prevention layer, and a via plug formed within the via hole.

A diffusion-prevention layer may be further formed on the reaction-prevention layer and the interlayer insulating layer, including the metal lines.

The diffusion-prevention layer may be formed of a nitride layer.

The metal lines may be formed from copper (Cu).

The reaction-prevention layer may be formed of any one of TaN, Ti and TiN or a stacked layer including two or more of TaN, Ti and TiN.

The via plug can be formed from tungsten (W).

The reaction-prevention layer can have a width wider than that of the via plug.

### BRIEF DESCRIPTION OF THE DRAWINGS

FIGS. 1A to 1C are diagrams illustrating problems occurring in a conventional manufacturing process of a flash memory device; and

FIGS. 2A to 2C are sectional views illustrating a method of fabricating a flash memory device in accordance with embodiments of the present invention.

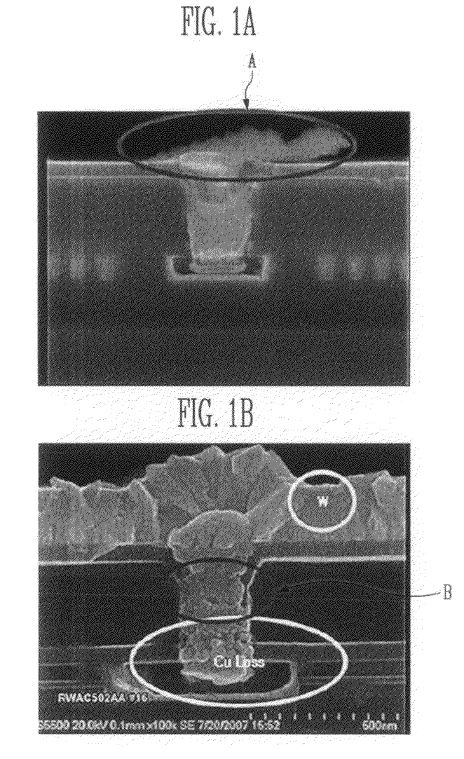

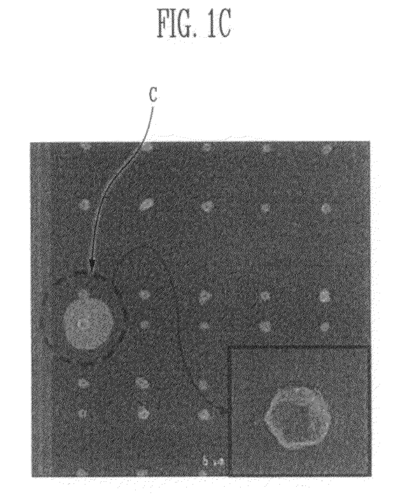

### DESCRIPTION OF SPECIFIC EMBODIMENT

Now, embodiments according to the present invention will be described with reference to the accompanying drawings. However, the present invention is not limited to the disclosed embodiments, but may be implemented in various ways. The embodiments are provided to complete the disclosure of the present invention and to allow those having ordinary skill in the art to understand the scope of the present invention. The present invention is defined by the category of the claims.

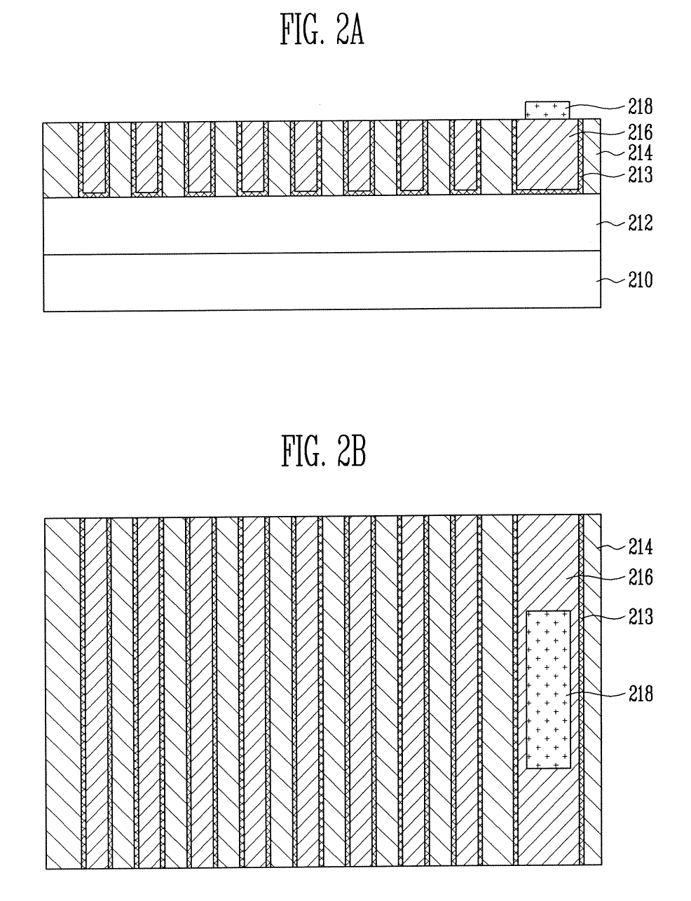

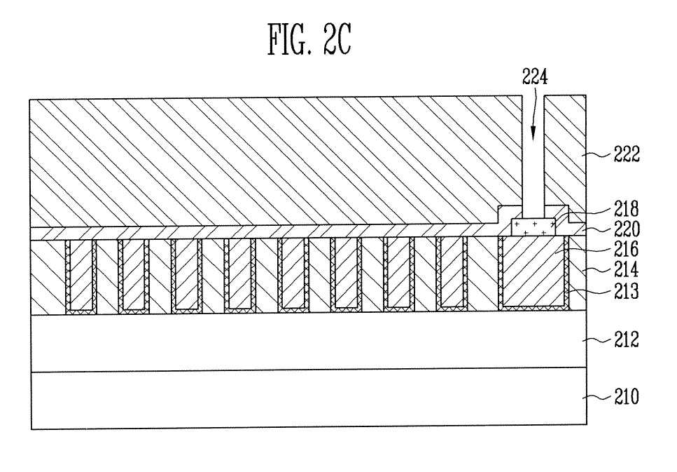

Referring to FIG. 2A, a reaction-prevention layer 218 is formed on a metal line of a region in which a via hole will be formed on a first interlayer insulating layer 214 including metal lines 216. More specifically, in a state where specific underlying structures (not shown) are provided on a semiconductor substrate 210, the first interlayer insulating layer 214 is formed over the semiconductor substrate 210 including the lower interlayer insulating layer 212. A plurality of damascene patterns is formed in the first interlayer insulating layer 214. The damascene patterns are gap-filled with conductive materials and, therefore, the metal lines 216 are formed within the damascene patterns. The metal lines 216 can be formed from copper (Cu). Meanwhile, a barrier metal layer barrier metal layer 213 for preventing metal components of the metal lines 216 from diffusing into the first interlayer insulating layer 214 can be formed between the metal lines 216 and the first interlayer insulating layer 214.

In the case of NAND flash memory devices, the metal lines 216 may become bit lines and some of the metal lines are formed in a well pick-up region.

Next, in a subsequent process, the reaction-prevention layer 218 for preventing materials of a via plug and materials of the metal lines 216 is formed on the metal line 216 of a region where the via plug will be formed. The reaction-prevention layer 218 can be formed from conductive materials. In the case in which the metal lines 216 are formed of copper (Cu) and the via plug is formed of tungsten (W) in a subsequent process, the reaction-prevention layer 218 is formed in order to prevent reliability of devices from being degraded due to reaction of copper (Cu) and tungsten (W). The reaction-prevention layer 218 can be formed of any one of tantalum nitride (TaN), titanium (Ti) and titanium nitride (TiN) or a stacked layer including two or more of them. The reaction-prevention layer 218 can have a width wider than that of the via plug. However, in the case in which a neighboring metal line and the reaction-prevention layer 218 are connected, failure may occur due to a bridge. Accordingly, the width of the reaction-prevention layer 218 has to be controlled in consideration of a distance between a neighboring metal line and the reaction-prevention layer 218.

Although it is shown in FIG. 2A that the reaction-prevention layer 218 is formed only on the metal line 216 of the well pick-up region, the reaction-prevention layer may be also formed in other regions in which via plugs will be formed.

As described above, the reaction-prevention layer 218 is formed on the metal line of the region in which the via hole will be formed before the via hole etch process. When the via hole etch process is performed, copper (Cu) ions of a lower copper (Cu) line is not directly exposed due to titanium nitride (TiN) included in the reaction-prevention layer 218. Tantalum nitride (TaN) can function to prevent copper (Cu) from diffusing. Accordingly, although some of a subsequent tungsten (W) plug metal barrier layer is not gap-filled in a deposition process of a metal barrier layer in order to form the tungsten (W) plug, copper (Cu) is not exposed since the reaction-prevention layer 218 having the conductive and copper (Cu) diffusion-prevention function is formed on the copper (Cu) line of the region in which the via hole will be formed. Thus, it is efficient in terms of the reliability of devices. FIG. 2B is a plan view of FIG. 2A.

Referring to FIG. 2C, a second interlayer insulating layer 222, including a via hole 224, is formed over the metal line 216, having the reaction-prevention layer 218 formed thereon, and the first interlayer insulating layer 214 including the remaining metal lines 216. More specifically, a diffusion-prevention layer 220 and the second interlayer insulating layer 222 are sequentially formed over the metal lines 216 on which the reaction-prevention layer 218 having the metal stacked structure is formed and the first interlayer insulating layer 214 including the remaining metal lines 216. The via hole 224 is formed by performing an etch process on the second interlayer insulating layer 222 and the diffusion-prevention layer 220 such that the reaction-prevention layer 218 is exposed partially by employing a via hole mask (not shown). At this time, the diffusion-prevention layer 220 is formed of nitride materials. The etch process of the second interlayer insulating layer 222 and the diffusion-prevention layer 220 can be performed in-situ by employing a proper process condition for each layer. Thereafter, a tungsten layer can be deposited on the inside of the via hole 224 in order to form a tungsten (W) via plug. Through this process, pattern issues and a bridge problem with a neighboring via hole, when a subsequent tungsten (W) via plug metal barrier layer and a tungsten layer are formed, can be solved. Accordingly, reliability of devices can be improved significantly.

Accordingly, before a via hole etch process is performed so as to form a via plug of a semiconductor device, the reaction-prevention layer of a tantalum nitride/titanium/titanium nitride (TaN/Ti/TiN) stacked structure, having a conductive and copper (Cu) diffusion-prevention function, is formed on a metal line of a region in which the via hole will be formed. The stacked structure may include two or more of tantalum nitride (TaN), titanium (Ti) and titanium nitride (TiN). That is, when the via hole etch process is performed, copper (Cu) ions of an underlying copper (Cu) line is not exposed directly due to titanium nitride (TiN) included in the reaction-prevention layer. This is because tantalum nitride (TaN) has the copper (Cu) diffusion-prevention function. Accordingly, the occurrence of pattern issues and a bridge with a neighboring via hole, when a subsequent tungsten (W) via plug metal barrier layer and a tungsten layer are formed, can be solved. Accordingly, reliability of devices can be improved significantly.

The embodiment disclosed herein has been proposed to allow a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

What is claimed is:

1. A method of fabricating a semiconductor device, comprising:
forming a plurality of metal lines over a semiconductor substrate;
forming a reaction-prevention layer on the metal line of a region in which a via hole will be formed;
forming an interlayer insulating layer over the semiconductor substrate including the reaction-prevention layer;
forming the via hole by etching the interlayer insulating layer over the reaction-prevention layer; and
forming a via plug within the via hole.

2. The method of claim 1, further comprising, after the reaction-prevention layer is formed, forming a diffusion-prevention layer on the interlayer insulating layer including the metal lines.

3. The method of claim 2, wherein the diffusion-prevention layer is formed of a nitride layer.

4. The method of claim 1, wherein the metal lines are formed from copper (Cu).

5. The method of claim 1, wherein the reaction-prevention layer is formed of any one of tantalum nitride (TaN), titanium (Ti) and titanium nitride (TiN) or a stacked layer including two or more of TaN, Ti and TiN.

6. The method of claim 1, wherein the via plug is formed from tungsten (W).

7. The method of claim 1, wherein the reaction-prevention layer has a width wider than that of the via plug.

8. A semiconductor device, comprising:
a plurality of metal lines formed over a semiconductor substrate;
a reaction-prevention layer formed on the metal line of a region in which a via hole will be formed;
an interlayer insulating layer including a via hole formed on the reaction-prevention layer; and
a via plug formed within the via hole.

9. The semiconductor device of claim 8, further comprising a diffusion-prevention layer formed on the reaction-prevention layer and the interlayer insulating layer, including the metal lines.

10. The semiconductor device of claim 9, wherein the diffusion-prevention layer is formed of a nitride layer.

11. The semiconductor device of claim 8, wherein the metal lines are formed from copper (Cu).

12. The semiconductor device of claim 8, wherein the reaction-prevention layer is formed of any one of tantalum nitride (TaN), titanium (Ti) and titanium nitride (TiN) or a stacked layer including two or more of TaN, Ti and TiN.

13. The semiconductor device of claim 8, wherein the via plug is formed from tungsten (W).

14. The semiconductor device of claim 8, wherein the reaction-prevention layer has a width wider than that of the via plug.
